(19) United States
(12) Patent Application Publication
(10) Pub. No.: US 2007/0082467 A1
(43) Pub. Date: Apr. 12, 2007

(54) Method for manufacturing compound semiconductor substrate

(75) Inventors: Masahiko Hata, Tsuchiura-shi (JP); Yoshinobu Ono, Tsukuba-gun (JP); Kazumasa Ueda, Tsuchiura-shi (JP)

Correspondence Address: FITCH, EVEN, TABIN & FLANNERY, P. O. BOX 18415, WASHINGTON, DC, 20036, US

(73) Assignee: Sumitomo Chemical Company, Limited, Tokyo (JP)

(21) Appl. No.: 10/577,069

(22) PCT Filed: Oct. 25, 2004
(86) PCT No.: PCT/JP04/16186

§ 371 Date: Jun. 20, 2006

(30) Foreign Application Priority Data
Oct. 27, 2003 (JP) 2003-365736

(51) Int. Cl. H01L 21/20; H01L 21/36; H01L 31/20; H01L 21/30; H01L 21/46

(52) U.S. Cl. 438/483; 438/458

(57) ABSTRACT

The present invention provides a method for manufacturing a compound semiconductor substrate. The method for manufacturing a compound semiconductor substrate comprises the steps of:
(a) epitaxially growing a compound semiconductor functional layer 2 on a substrate 1,
(b) bonding a support substrate 3 to the compound semiconductor functional layer 2,
(c) polishing the substrate 1 and a part of the compound semiconductor functional layer 2 on the side which is in contact with the substrate 1, to remove them,
(d) bonding a thermally conductive substrate 4 having a thermal conductivity higher than that of the substrate 1 to the exposed surface of the compound semiconductor functional layer 2 which is provided in the step (c) to obtain a multilayer substrate and
(d) separating the support substrate 3 from the multilayer substrate.

### TECHNICAL FIELD

The present invention relates to a method for manufacturing a compound semiconductor substrate.

### BACKGROUND OF THE ART

A compound semiconductor substrate has been used for manufacturing electronic devices such as field-effect transistor, heterojunction bipolar transistor, etc. It is known that, when these electronic devices are operated at a high current density, temperature of the electronic devices rises to result in deterioration in performances of the electronic devices such as current amplification factor of transistor and rectification property of diode and degradation in reliability. In order to reduce temperature elevation of the electronic devices, a method for manufacturing the compound semiconductor substrate which is excellent in heat radiation has been studied.

### DISCLOSURE OF THE INVENTION

The object of the invention is to provide a method for manufacturing a compound semiconductor substrate which is excellent in heat radiation.

The present inventors have studied a method for easily manufacturing the compound semiconductor substrate which is excellent in heat radiation, and resultantly leading to completion of the invention.

Namely, the present invention provides a method for manufacturing a compound semiconductor substrate comprising the steps of (a)-(e):
(a) epitaxially growing a compound semiconductor functional layer 2 on a substrate 1,
(b) bonding a support substrate 3 to the compound semiconductor functional layer 2,
(c) polishing the substrate 1 and a part of the compound semiconductor functional layer 2 on the side which is in contact with the substrate 1, to remove them,
(d) bonding a thermally conductive substrate 4 having a thermal conductivity higher than that of the substrate 1 to the exposed surface of the compound semiconductor functional layer 2 which is provided in the step (c) to obtain a multilayer substrate and
(e) separating the support substrate 3 from the multilayer substrate.

Further, the present invention provides a method for manufacturing a compound semiconductor substrate comprising the steps of (f)-(h):
(f) epitaxially growing a compound semiconductor functional layer 22 on a substrate 21,
(g) bonding a thermally conductive substrate 23 having a thermal conductivity higher than that of the substrate 21 to the surface of the compound semiconductor functional layer 22 and
(h) polishing the substrate 21 and a part of the compound semiconductor functional layer 22 on the side which is in contact with the substrate 21, to remove them.

The compound semiconductor substrate obtained by the method according to the present invention is excellent in heat radiation. The compound semiconductor substrate is used as a material for manufacturing to obtain electronic devices such as transistor and heterojunction bipolar transistor having a high current amplification factor, and diode of excellent rectification property. These electronic devices are excellent in terms of performances and reliability, since temperature elevation of their devices is reduced even when operated at a high current density.

### BRIEF DESCRIPTION OF THE DRAWINGS

FIG. 1 shows an embodiment (example 1) of the present invention.

FIG. 2 shows an embodiment (example 2) of the present invention.

FIG. 3 shows a cross section structure of a pn junction diode obtained in the example 2.

FIG. 4 shows current-voltage characteristics of the pn junction diode obtained in the example 2.

FIG. 5 shows a cross section structure of a pn junction diode obtained in a comparative example 2.

FIG. 6 shows current-voltage characteristics of the pn junction diode obtained in the comparative example 2.

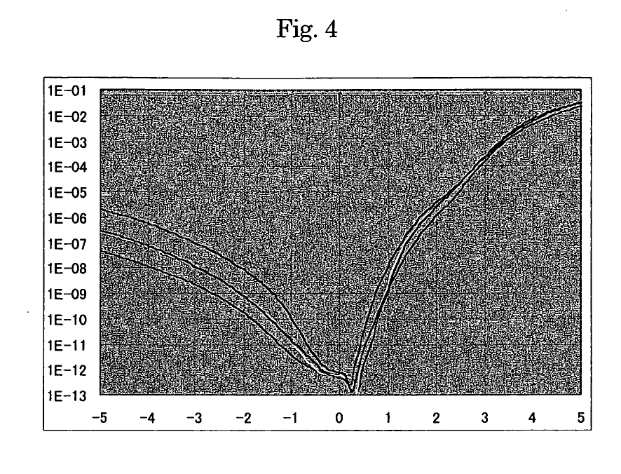

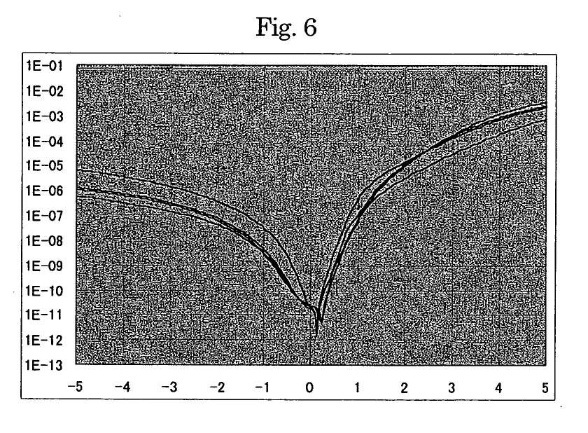

In FIG. 4 and FIG. 6, a longitudinal axis represents current value I flowing between a p-electrode and an n-electrode, of which the unit is A (ampere), and a horizontal axis represents voltage V applied to the p-electrode and the n-electrode, of which the unit is V (volt).

### BEST MODES FOR CARRYING OUT THE INVENTION

Method I for Manufacturing Compound Semiconductor Substrate

A method I for manufacturing a compound semiconductor substrate comprises the steps of (a) to (e).

Examples of substrate 1 used in the step (a) include single crystal substrates such as single crystal GaAs, single crystal InP, or sapphire. As these substrates 1, commercially available products may be used. The substrate 1 with its surface cleaned up is preferably used.

The compound semiconductor functional layer 2 in the step (a) is epitaxially grown. Examples of the epitaxial growth include metal organic chemical vapor deposition (MOCVD), molecular beam epitaxy, halide chemical vapor deposition (which uses a gas containing halogen as a starting material), hydride vapor phase epitaxy, liquid phase epitaxy. Preferably, the compound semiconductor functional layer 2 consists of at least two layers. More preferably, respective layers include at least one III group element selected from the group consisting of In, Ga, and Al and further include at least one V group element selected from the group consisting of N, P, As, and Sb. In the present specification, elements except for In, Ga, Al, N, P, As, and Sb are dopant. In the present specification, in terms of layers constituting the compound semiconductor functional layer 2, layers which are different in composition or the dopant level are regarded as different. Thus, examples of the compound semiconductor functional layer 2 include a layer consisting of a compound semiconductor functional layer 2A and a compound semiconductor functional layer 2B with the same composition as and a different dopant level from the compound semiconductor functional layer 2A.

A support substrate 3 in the step (b) is bonded to an epitaxial growth surface of the compound semiconductor layer containing the compound semiconductor functional layer 2. The support substrate 3 is a substrate for adding to the strength of the compound semiconductor substrate so as to prevent it from breakage in the following steps, and may need sufficient mechanical strength. Examples of the support substrate 3 include insulating glass and ceramic such as quartz and sapphire; and a semiconductive material such as Si and Ge.

Bonding in the step (b) may be performed by using an adhesive. The adhesive is one which provides bonding strength enough not to separate the support substrate 3 from the compound semiconductor functional layer 2 in the following step (c) and to be removed from the epitaxial growth surface without providing any chemical and physical changes on the epitaxial growth surface (without causing chemical and physical damages) in the step (e) and examples thereof include electron wax and adhesive tape.

In the step (c), the substrate 1 and a part of the compound semiconductor functional layer 2 located adjacent to the substrate 1 are polished to remove. Examples of the compound semiconductor functional layer 2 to be polished include a layer (buffer layer etc.) which is useful for crystal growth when the epitaxial growth is performed. Examples of polishing include mechanical polishing, chemical mechanical polishing, chemical polishing. The mechanical polishing is performed by pressing a polished material against a polishing machine with a proper stress in the presence of polishing material or polishing chemical. The chemical mechanical polishing is performed by combining mechanical polishing with dissolution of a polished surface using a polishing chemical, and spraying liquid such as water containing the polishing material or polishing chemical into the vicinity of a boundary face between a substrate and a compound semiconductor functional layer as a narrow flow at high pressure, followed by separating the substrate from the compound semiconductor functional layer through the chemical and mechanical polishing process. The chemical polishing is performed through corrosion and dissolution with liquid polishing chemicals or through corrosion and volatilization with gas.

In the step (d), a thermally conductive substrate 4 having a thermal conductivity higher than that of the substrate 1 is bonded to the surface of the compound semiconductor functional layer 2 exposed after the whole of the substrate 1 and a part of the compound semiconductor functional layer 2 located adjacent to the substrate 1 are removed. The thermally conductive substrate 4 may have usually the same size as the substrate 1, or larger size than the substrate 1. Example of the thermally conductive substrate 4 include diamond; silicon carbide (SiC); aluminum nitride (AlN); boron nitride (BN); silicon (Si); metal such as Al, Cu, Fe, Mo, and W; metal oxide; and metal boride. The metal may be alloy, and examples thereof include at least two alloys selected from the group consisting of Al, Cu, Fe, Mo and W. The thermally conductive substrate 4 includes preferably diamond; SiC; AlN; BN; Si; Al, Cu, Fe, Mo, W, and alloy of these metals.

The thermally conductive substrate 4 includes more preferably polycrystalline Si substrate obtained by chemical vapor deposition (CVD) or sintering process; a substrate formed with a polycrystalline or amorphous diamond thin film (hereinafter referred to as “diamond substrate”) having a thickness of about not more than 300 μm, preferably about not more than 150 μm and about not less than 50 μm on a single crystal Si substrate, polycrystalline Si substrate or ceramic substrate (SiC, AlN, BN, etc.); a polycrystalline or amorphous SiC, AlN, and BN obtained by CVD or sintering process.

Among these, the diamond substrate is preferable, the diamond substrate of which the diamond thin film is amorphous is more preferable. The diamond substrate is available relatively easily, has high thermal conductivity (>1000 W/mK), and contains the Si substrate or the ceramic substrate with high strength, thus, handling ability is good.

In operation of electronic devices, along with generation of heat, temperature gradient occurs from a side of the electronic devices toward a side of the thermally conductive substrate 4. Then, tensile or compressive stress is induced based on a coefficient difference in thermal expansion between the compound semiconductor functional layer 2 and thermally conductive substrate 4 bonded to the compound semiconductor functional layer 2 and thus the thermally conductive substrate 4 has preferably a thermal expansion coefficient close to that of the compound semiconductor functional layer 2.

Further, the thermally conductive substrate 4 has a thermal conductivity of not less than about 100 W/mK, preferably not less than about 150 W/mK, more preferably not less than about 500 W/mK, which is higher than thermal conductivity of substrate 1 (from about 40 W/mK to about 70 W/mK) such as GaAs single crystal substrate, InP single crystal substrate, and sapphire substrate.

When manufacturing a high frequency electronic device from the compound semiconductor substrate, in view of reducing dielectric loss at the higher frequencies, the thermally conductive substrate 4 in the compound semiconductor substrate has a resistivity of preferably about not less than 10³ Ωcm, more preferably about not less than 10⁵ Ωcm. While, in applications not requiring low dielectric loss at the high frequencies, the thermally conductive substrate 4 may be various semiconductor; ceramic (SiC, AlN, Bn, etc.); electric conductive material (metal, metal oxide, metal boride, etc.).

Bonding in the step (d) may be performed using adhesive, and may be performed by a method without using the adhesive. When using the adhesive, examples of the adhesive include an inorganic adhesive such as low melting point metal (In, Sn or solder, etc); an organic adhesive such as thermosetting resin, photopolymerizable resin, electron wax (Wax “W” manufactured by Apiezon, etc.), preferably the organic adhesive. When both of the thermally conductive substrate 4 and the compound semiconductor functional layer 2 are optically transparent, the adhesive containing the photopolymerizable resin may be used. The adhesive has preferably a layer thickness which is a level not to impair heat transmission from the compound semiconductor functional layer 2 to the thermally conductive substrate 4.

In the step (d), before bonding the compound semiconductor functional layer 2 with the thermally conductive substrate 4, at least one of bonding faces of these is preferably subjected to cleanup treatment or chemical treatment. Also, at least one of the bonding faces treated the above is more preferably subjected to thermal treatment. These treatments enable the compound semiconductor-functional layer 2 to be directly bonded with the thermally conductive substrate 4. (See, for instance, Journal of Optical Physics and Materials, Vol. 6 No. 1, 1997, P19-48.) In direct bonding, coefficient difference in thermal expansion between the compound semiconductor functional layer 2 and the thermally conductive substrate 4 is preferably small.

In the step (e), the support substrate 3 is separated from the multilayer substrate including the thermally conductive substrate 4, the compound semiconductor functional layer 2, and the support substrate 3 in this order, which is obtained in the step (d), to obtain a compound semiconductor substrate. Separation may be performed by, for instance, a method of melting the adhesive by heating. In the case of electron wax, the electron wax may be melted by heating, followed by separating the support substrate 3, thereafter, removing the electron wax remaining on the compound semiconductor substrate using an organic solvent.

Method II for Manufacturing Compound Semiconductor Substrate

A method II for manufacturing a compound semiconductor substrate of the present invention comprises the steps of (f) to (h).

The step (f) may be performed according to the same operation as the step (a). A substrate 21 is made of the same one as the substrate 1.

In the step (g), according to the step (d), a compound semiconductor layer 22 may be bonded to a thermally conductive substrate 23 using adhesive, and a compound semiconductor layer 22 may be bonded to a thermally conductive substrate 23 by a method without using the adhesive. For the adhesive, the adhesive used in the step (d) may be applied. A compound semiconductor functional layer 22 and a thermally conductive substrate 23 correspond to the compound semiconductor functional layer 2 and the thermally conductive substrate 4, respectively.

In the step (h), according to the step (c), a substrate 21 and a part of the compound semiconductor layer 22 located adjacent to the substrate 21 may be polished to remove. Polishing may be performed according to the same operation as the step (c)

The compound semiconductor substrate obtained by the method I and II for manufacturing the compound semiconductor substrate of the present invention may be cut away with the peripheral portion in view of preventing breakage and missing of the compound semiconductor substrate in manufacturing or in transporting products, and if necessary, may be formed into shapes suitable for manufacturing steps of electronic devices. Cutting away of the peripheral portion may be carried out after a final step of the method for manufacturing the compound semiconductor substrate of the present invention or in the middle of these steps.

Further, the compound semiconductor substrate obtained by the method I (or II) for manufacturing the compound semiconductor substrate of the present invention is usually the same as the substrate 1 (or 21) in dimension and shape, conventional facilities are applicable to a facility for manufacturing the electronic devices using this compound semiconductor substrate.

Method for Manufacturing Electronic Device

A method for manufacturing an electronic device of the present comprises the step of forming an electrode on the compound semiconductor substrate obtained the above.

Formation of the electrode may be carried out by, for instance, a method of vapor depositing metal (Au, Ti, Ni, Al, Ge, etc.) on the compound semiconductor layer 2 (or 22) of the compound semiconductor substrate. If necessary, dry etching or aqua regina treatment may be performed in the formation of the electrode.

### EXAMPLES

The present invention is described in more detail by following Examples, which should not be construed as a limitation upon the scope of the present invention.

### Example 1 PS [Manufacturing of Compound Semiconductor Substrate]

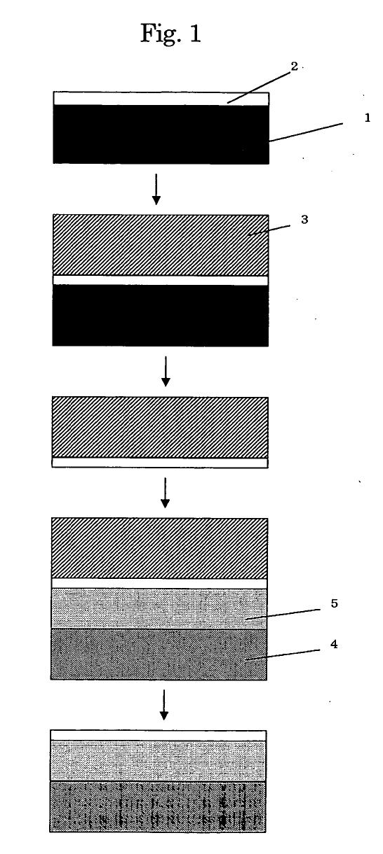

FIG. 1 shows a procedure for manufacturing a compound semiconductor.

On a single crystal semi-insulating GaAs substrate 1 having a diameter of 100 mm and a thickness of 630 μm which is commercially available, a compound semiconductor functional layer 2 for a heterojunction bipolar transistor was grown by metal organic vapor-phase thermal decomposition using hydrogen gas as a carrier,

trimethyl gallium, triethyl gallium, trimethyl aluminum, and trimethyl indium as a starting material containing III group element;

arsine and phosphine as a starting material containing V group element; and

disilane (n-type control) and trichloro-bromomethane (p-type control) as a raw material of a dopant for conductivity control, to produce a compound semiconductor layer substrate.

A layer structure of the compound semiconductor functional layer 2 was described in order from the substrate 1 side, as follows:

| | |
|---|---|
| undoped GaAs layer | 50 nm |
| undoped AlAs layer | 50 nm |
| undoped GaAs layer | 500 nm |
| Si-doped (electron density 3 × 10¹⁸/cm³) | 500 nm |
| n-type GaAs subcollector layer | |
| Si-doped (electron density 1 × 10¹⁶/cm³) | 500 nm |
| n-type GaAs collector layer | |
| C-doped (positive hole density 4 × 10¹⁹/cm³) | 80 nm |
| p-type GaAs base layer | |
| Si-doped (electron density 3 × 10¹⁷/cm³) | 30 nm |
| n-type InGaP emitter layer | |
| Si-doped (electron density 3 × 10¹⁸/cm³) | 100 nm |
| n-type GaAs subemitter layer | |
| Si-doped (electron density 2 × 10¹⁹/cm³) | 100 nm |
| n-type InₓGa₁₋ₓAs (x = 0 to 0.5 gradient | |
| structure) contact layer | |

In FIG. 1, these layers were represented as a compound semiconductor functional layer 2 as a whole.

A transparent quartz support substrate 3 having a diameter of 100 mm and a thickness of 500 μm was placed on a hot plate heated to about 100° C., followed by applying and dissolving electron wax. A surface of epitaxial growth of the compound semiconductor functional layer 2 of the compound semiconductor layer substrate was bonded to the support substrate 3 as a bonding face. At this time, a load of about 5 kg was applied via a jig from the back side of the compound semiconductor layer substrate, followed by applying the electron wax uniformly on the bonding face, and thereafter, stopping heating the hot plate, thereby solidifying the electron wax, to obtain a multilayer substrate supported by the transparent quartz support substrate 3. The multilayer substrate had a thickness of 1130 μm which was measured using a dial gauge.

The support substrate 3 of the multilayer substrate was fixed on a polishing machine, and a GaAs substrate 1 was subjected to mechanical polishing for about 20 min. to remove by about 580 μm. The multilayer substrate was taken off the polishing machine and washed with water. Then, the multilayer substrate was immersed in citric acid/hydrogen peroxide/water-based etching solution and etched for 4 hours, followed by dissolving the GaAs substrate 1 and the whole of a GaAs layer grown epitaxially which is on the substrate side of an AlAs layer. After water washing, the multilayer substrate was immersed in 5% HF aqueous solution for 3 minutes to remove the AlAs layer.

On a single crystal Si substrate 4 having a diameter of about 100 mm and a thickness of about 500 μm which is commercially available, a high resistance insulating diamond thin film 5 having a thickness of about 50 μm was formed by plasma CVD using hydrogen and methane as a raw material. The diamond thin film 5 was subjected to mirror polishing to obtain a surface. A polyimide aqueous solution was spin-coated on the surface to obtain a coated surface. The coated surface was contacted with a polished surface of the compound semiconductor functional layer 2 (which was obtained by removing a single crystal GaAs substrate 1, was bonded to the support substrate 3 and supported thereby). Thereafter, by heating to about 100° C. to bond both surfaces, at the same time, to dissolve electron wax, the support substrate 3 was removed. Heating was carried out under the conditions of atmosphere: nitrogen, applied load: about 20 kg, temperature: about 300° C., and time period: 1 hour to obtain a compound semiconductor substrate having a sufficient bonding strength.

[Manufacturing and Evaluation of Transistor]

An epitaxial growth surface of the compound semiconductor functional layer 2 of the compound semiconductor substrate was cleaned up by ultrasonic cleaning with acetone, thereafter, a heterojunction bipolar transistor of which dimension of an emitter surface is 100 μm×100 μm was manufactured using conventional lithography. AuGe/Ni/Au was used as a collector metal and Ti/Au as an emitter metal and a base metal. Current amplification factor was 148 at collector current density of 1 kA/cm²h.

### Comparative Example 1

The same operations as [Manufacturing of compound semiconductor substrate] of Example 1 were performed except that a GaAs single crystal substrate 1 was not removed and a thermally conductive substrate 4 was not bonded thereto, to obtain a compound semiconductor substrate.

The compound semiconductor substrate was subjected to the same operations as [Manufacturing and evaluation of transistor] of Example 1. The obtained heterojunction bipolar transistor of which dimension of an emitter surface is 100 μm×100 μm had a current amplification factor of 132 at collector current density of 1 kA/cm²h.

### Example 2

[Manufacturing of Compound Semiconductor Substrate]

On a single crystal insulating sapphire substrate 1′ having a diameter of 50 mm and a thickness of 500 μm which is commercially available, a compound semiconductor functional layer 2′ for a pn junction diode was grown by metal organic vapor-phase thermal decomposition using

hydrogen gas as a carrier,

trimethyl gallium, and trimethyl aluminum as a starting material containing III group element; ammonia as a starting material containing V group element; and

silane (n-type control) and bis(cyclopentadienyl)magnesium (p-type control) as a raw material of a dopant for conductivity control to produce a compound semiconductor layer substrate.

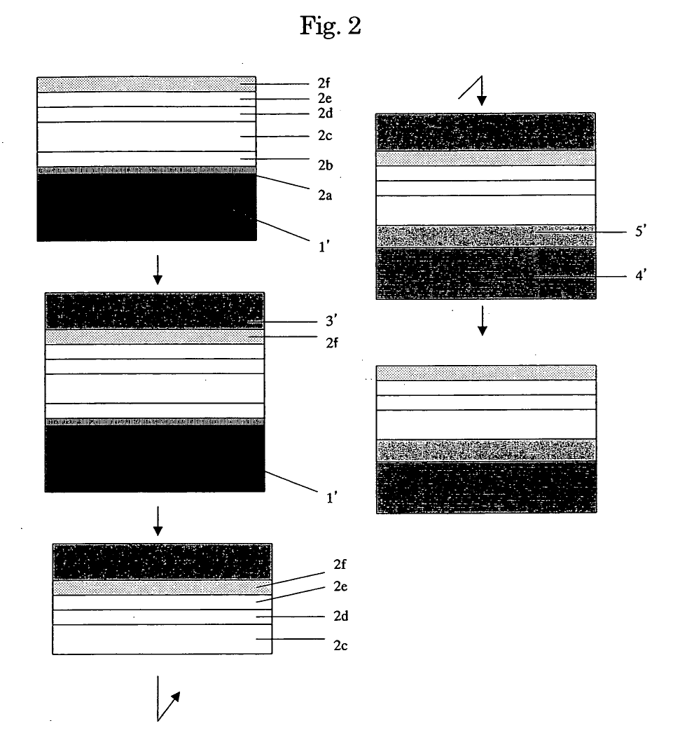

A layer structure of the compound semiconductor functional layer 2′ was described in order from the substrate 1′ side as follows (see FIG. 2):

| | |
|---|---|
| undoped GaN buffer layer 2a | 20 nm |
| undoped GaN layer 2b | 500 nm |
| Si-doped (electron density 3 × 10¹⁸/cm³) | 5000 nm |
| n-type GaN layer 2c | |
| undoped GaN layer 2d | 50 nm |
| undoped AlₓGa₁₋ₓN (x = 0.05) layer 2e | 30 nm |
| Mg-doped (positive hole density 8 × 10¹⁸/cm³) | 80 nm |
| p-type GaN layer 2f | |

The compound semiconductor layer substrate was subjected to thermal treatment for 10 min. at about 500° C. under nitrogen gas atmosphere to activate the p-type GaN layer 2f.

A transparent quartz support substrate 3′ having a diameter of 50 mm and a thickness of 500 μm was placed on a hot plate heated to about 100° C., followed by applying and dissolving electron wax.

An epitaxial growth surface in the compound semiconductor functional layer 2′ of the compound semiconductor layer substrate was bonded to the support substrate 3′ as a bonding face. At this time, a load of approx. 5 kg was applied via a jig from the back side of the compound semiconductor layer substrate, followed by applying the electron wax uniformly on the bonding face, and thereafter, stopping heating the hot plate, thereby solidifying the electron wax, to obtain a multilayer substrate supported by the support substrate 3′. The multilayer substrate had a thickness of 1006 μm which was measured using a dial gauge.

The support substrate 3′ of the multilayer substrate was fixed on a polishing machine, and a sapphire substrate 1′ was subjected to mechanical polishing for about 40 min. to remove by about 480 μm and further by 22 μm using a finer abrasive polishing which was exchanged with a polishing agent and a polishing pad. The compound semiconductor layer substrate was taken off the polishing machine and the multilayer substrate washed with water and further washed with aqua regia. Then, the GaN surface exposed by about 0.5 μm was subjected to chemical polishing, washed with water and dried to obtain the compound semiconductor layer substrate.

On a single crystal Si substrate 4′ having a diameter of 50 mm and a thickness of about 500 μm which was commercially available, a high resistance insulating diamond thin film 5′ having a thickness of about 50 μm was formed by plasma CVD using hydrogen and methane as a raw material.

The diamond thin film 5′ was subjected to mirror polishing to obtain a surface. A polyimide aqueous solution was spin-coated on the surface to obtain a coated surface. The coated surface was contacted with a polished surface of the compound semiconductor functional layer 2. Thereafter, by heating to about 100° C. to bond both surfaces, at the same time, to dissolve electron wax, the support substrate 3′ was removed. Heating was carried out under the conditions of atmosphere: nitrogen, applied load: about 20 kg, temperature: about 300° C., and time period: 1 hour to obtain a compound semiconductor substrate having a sufficient bonding strength.

[Manufacturing and Evaluation of Diode]

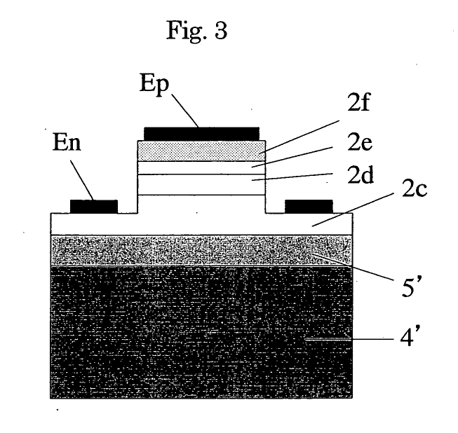

An Au/Ni electrode having a diameter of 300 μm was vapor-deposited on the surface of a p-type GaN layer 2f, and then was subjected to thermal treatment at 400° C. for 5 min. to form a p-type ohmic electrode Ep. The periphery of the p-type ohmic electrode Ep of the compound semiconductor substrate was removed by about 1000 nm by dry etching, and etched back by 50 nm with aqua regia treatment. Al metal was vapor-deposited by 500 nm on the surface, followed by forming an n-type ohmic electrode En to produce a mesa-structure GaN/AlGaN pn heterojunction diode including an aluminum n-side ohmic electrode En connected with n-type GaN side and the p-side ohmic electrode Ep connected with p-type GaN. The cross section structure thereof is shown in FIG. 3. Current-voltage characteristic of the diode was measured on the obtained 4 samples. The results were shown in FIG. 4

### Comparative Example 2

The same operations as [Manufacturing of compound semiconductor substrate] of Example 2 were performed except that a sapphire substrate 1′ was not removed and a thermally conductive substrate was not bonded thereto (with a high resistance insulating diamond thin film 5′ formed on a single crystal Si substrate 4′) to obtain a compound semiconductor substrate.

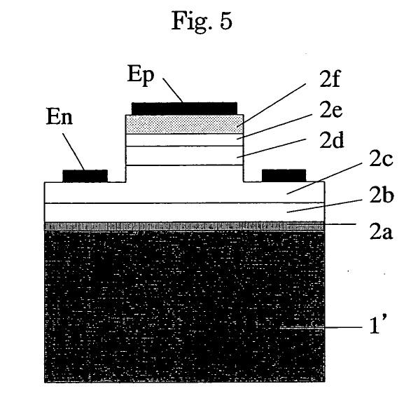

The compound semiconductor substrate was subjected to the same operations as [Manufacturing and evaluation of diode] of Example 2 to obtain a mesa-structure GaN/AlGaN pn heterojunction diode including an aluminum n-side ohmic electrode connected with n-type GaN side and the p-side ohmic electrode connected with p-type GaN. The cross section structure of the resultant diode is shown in FIG. 5. In FIG. 5, 1′ represents sapphire substrate, 2a as undoped GaN buffer layer, 2b as undoped GaN layer, 2c as Si-doped n-type GaN layer, 2d as undoped GaN layer, 2e as undoped AlₓGa₁₋ₓN (x=0.05), 2f as Mg-doped p-type GaN layer, Ep as p-side ohmic electrode, En as n-side ohmic electrode.

Current-voltage characteristic of the diode was measured on the obtained 4 samples. The results were shown in FIG. 6.

As shown in FIG. 4, the diode (Example 2) obtained by the method for manufacturing the compound semiconductor of the present invention is large in current value of a side of forward bias (applied voltage value of horizontal axis >0V) and small in leakage current value of a side of reverse bias (applied voltage value of horizontal axis <0V), further excellent in rectification property.

As shown in FIG. 6, the diode (Comparative Example 2) obtained by a conventional method is small in current value of the side of forward bias and large in leakage current value of the side of reverse bias.

1. A method for manufacturing a compound semiconductor substrate, comprising the steps of:
(a) epitaxially growing a compound semiconductor functional layer 2 on a substrate 1,
(b) bonding a support substrate 3 to the compound semiconductor functional layer 2,
(c) polishing the substrate 1 and a part of the compound semiconductor functional layer 2 on the side which is in contact with the substrate 1, to remove them,
(d) bonding a thermally conductive substrate 4 having a thermal conductivity higher than that of the substrate 1 to the exposed surface of the compound semiconductor functional layer 2 which is provided in the step (c) to obtain a multilayer substrate and
(e) separating the support substrate 3 from the multilayer substrate.

2. The method according to claim 1, wherein the compound semiconductor functional layer 2 includes at least two layers.

3. The method according to claim 1, wherein the compound semiconductor functional layer 2 includes at least one selected from the group consisting of In, Ga, and Al and at least one selected from the group consisting of N, P, As, and Sb.

4. The method according to claim 1, wherein the thermally conductive substrate 4 includes at least one selected from the group consisting of Al, Cu, Fe, Mo, W, diamond, SiC, AlN, BN, and Si.

5. A method for manufacturing a compound semiconductor substrate, comprising the steps of:
(f) epitaxially growing a compound semiconductor functional layer 22 on a substrate 21,
(g) bonding a thermally conductive substrate 23 having a thermal conductivity higher than that of the substrate 21 to the surface of the compound semiconductor functional layer 22 and
(h) polishing the substrate 21 and a part of the compound semiconductor functional layer 22 on the side which is in contact with the substrate 21 to remove them.

6. The method according to claim 5, wherein the compound semiconductor functional layer 2 includes at least two layers.

7. The method according to claim 5, wherein the compound semiconductor functional layer 2 includes at least one selected from the group consisting of In, Ga, and Al and at least one selected from the group consisting of N, P, As, and Sb.

8. The method according to claim 5, wherein the thermally conductive substrate 23 includes at least one selected from the group consisting of Al, Cu, Fe, Mo, W, diamond, SiC, AlN, BN, and Si.

9. A method for manufacturing a electronic device, comprising the steps in the method according to claim 1 and a step of forming an electrode on the resultant compound semiconductor substrate.
